(19) United States
(12) Patent Application Publication
(10) Pub. No.: US 2026/0369526 A1
(43) Pub. Date: Nov. 19, 2026

(54) ENHANCED ALD FILM GROWTH WITH PULSING BOTTOM RF POWER

(71) Applicant: ASM IP Holding B.V., Almere (NL)

(72) Inventors: Jihye Yang, Ansan-si (KR); SangHeon Yong, Yongin-si (KR); JuHyuk Park, Hwaseong-si (KR); KiHun Kim, Yongin-si (KR)

(21) Appl. No.: 19/673,064

(22) Filed: May 11, 2026

Related U.S. Application Data
(60) Provisional application No. 63/805,661, filed on May 14, 2025.

(51) Int. Cl. H01J 37/32; C23C 16/44; C23C 16/448; C23C 16/455

(52) U.S. Cl. CPC H01J 37/32146; C23C 16/4408; C23C 16/4488; C23C 16/45538; C23C 16/45544; C23C 16/45553; H01J 37/321; H01J 37/32449; H01J 37/32522; H01J 37/32816; H01J 2237/3321; H01J 2237/3323

(57) ABSTRACT

A method for forming a film between a gap over a substrate is provided. The method includes introducing the substrate on a substrate support in a reaction chamber, and introducing a precursor into the reaction chamber. The method also includes reacting the precursor with a surface of the substrate, and introducing a plasma into the reaction chamber from a plasma source. The method includes introducing a reactant gas into the reaction chamber, and pulsing a RF power source connected to the substrate support. The method includes generating reactive species from the reactant gas while the plasma source and the RF power source are both activated. The method includes reacting the reactive species with the precursor on the surface to form the film over the substrate.

### CROSS-REFERENCE TO RELATED APPLICATIONS

This application claims priority to U.S. Provisional Patent Application Ser. No. 63/805,661 filed May 14, 2025 titled ENHANCED ALD FILM GROWTH WITH PULSING BOTTOM RF POWER, the disclosure of which is hereby incorporated by reference in its entirety.

### BACKGROUND OF THE INVENTION

### Field of the Invention

The present invention relates methods and systems for enhanced ALD film growth in a deposition chamber while pulsing a bottom RF power, and, in particular, to methods and systems for a for enhanced ALD film growth with uniform thickness.

### Background

Fabricating modern semiconductor devices requires the accurate deposition of materials with carefully controlled thicknesses and compositions. Ideally, the desired material compositions could be deposited directly in a single-step process, but often this is not feasible and it becomes necessary to deposit a material layer and then convert it into a layer with the desired elemental composition and properties. Using a CVD process with a precursor chemical containing the desired elements would be an option, but this would lead to issues with film conformality as well as controlling the composition. There is an alternative processing scheme that can be used to enhance the useability of CVD precursors, in which the precursors are exposed to a low-power plasma that partially breaks down the molecules to create more reactive species that are more likely to stick to the substrate surface. This so-called precursor radicalization approach makes CVD precursors available to ALD processing, and it requires a way to expose the precursor flow to direct plasma without affecting the substrate.

Plasma-enhanced atomic layer deposition (PEALD) is a widely used deposition method where plasma is used to create energetic ions and reactive radicals that can greatly benefit the deposition process. However, due to the inherently anisotropic nature of the ion flux on the substrate, PEALD processes often experience issues with conformality of the deposited film. To counter this, radical-enhanced ALD (REALD) was developed as a variant of PEALD in which the ions formed in the plasma sheath are not allowed to reach the substrate and film growth relies only on the reactive radicals in the plasma. This approach leads to a process with characteristics between PEALD and thermal ALD, and it can be very useful especially for applications requiring high levels of conformality. Some applications, however, would benefit from the possibility of using both direct plasma processing and radical exposure in the same process.

### BRIEF SUMMARY OF THE INVENTION

An embodiment of the present invention provides a method for forming a film between a gap over a substrate is provided. The method includes introducing the substrate on a substrate support in a reaction chamber, and introducing a precursor into the reaction chamber, reacting the precursor with a surface of the substrate, and introducing a plasma into the reaction chamber from a plasma source. The method includes introducing a reactant gas into the reaction chamber, pulsing a RF power source connected to the substrate support, generating reactive species from the reactant gas while the plasma source and the RF power source are both activated, and reacting the reactive species with the precursor on the surface to form the film over the substrate.

In some embodiments, the precursor comprises silane, disilane, trisilane, di(isopropylamino)silane, dichlorosilane, trichlorosilane, or monomethylsilane. In some embodiments, the reactant gas includes oxygen or hydrogen peroxide. In some embodiments, the period of time of introducing the plasma into the reaction chamber is substantially the same as the period of time of pulsing the RF power source connected to the substrate support. In some embodiments, the method further includes a purge step after introducing the precursor into the reaction chamber, and before introducing the reactant gas into the reaction chamber. In some embodiments, the flow rate of the introduced precursor is higher than 0 and lower than 3000 sccm. In some embodiments, the flow rate of the introduced reactant gas is higher than 0 and lower than 3000 sccm. In some embodiments, the power of the plasma source is higher than 0 and lower than 6000 W. In some embodiments, the power of the RF power source is higher than 0 and lower than 1000 W. In some embodiments, the duty cycle of the RF power source is higher than 10% and lower than 90%. In some embodiments, the pulse frequency of the RF power is higher than 0 and lower than 100 kHz. In some embodiments, the RF frequency of the RF power is higher than 13.56 MHz and lower than 60 MHz. In some embodiments, the process pressure of reacting the reactant gas with the precursor is higher than 1 torr and lower than 9 torr. In some embodiments, the process temperature of reacting the reactant gas with the precursor is higher than 0 °C and lower than 1000 °C.

An embodiment of the present invention provides a method for forming a material between a gap over a substrate. The method includes introducing the substrate on a substrate support in a reaction chamber, and introducing a precursor into the reaction chamber, reacting the precursor with a surface of the substrate, and purging the reaction chamber with an inert gas after the precursor is reacted. The method includes introducing a reactant gas into the reaction chamber after the reaction chamber is purged, activating a plasma source to introduce a plasma into the reaction chamber, pulsing a RF power source connected to the substrate support, and generating reactive species from the reactant gas while the plasma source and the RF power source are both activated. The method also includes reacting the reactive species with the reacted precursor to form the material between the gap, and deactivating the plasma source when the pulse of the RF power source ends.

In some embodiments, the method further includes introducing the inert gas into the reaction chamber while the precursor and the reactant gas are introduced into the reaction chamber. In some embodiments, the method further includes purging the reaction chamber with the inert gas after the plasma source is deactivated.

An embodiment of the present invention provides a semiconductor processing apparatus, including a reaction chamber and a plasma source, which is located at an upper portion of the reaction chamber. The semiconductor processing apparatus includes a substrate support, which is located at a lower portion of the reaction chamber and supporting a substrate. The semiconductor processing apparatus includes an ion filter, which is located between the plasma source and the substrate support. The semiconductor processing apparatus includes a RF power source, which is connected to the substrate support and configured to distribute plasma redial on the substrate. The semiconductor processing apparatus also includes a precursor source and a reactant source in fluid communication with the reaction chamber.

In some embodiments, the semiconductor processing apparatus further comprises a controller, which is configured to: introducing a precursor from the precursor source into the reaction chamber; purging the reaction chamber after the precursor is introduced; introducing a reactant gas from the reactant source into the reaction chamber; activating the plasma source and pulsing the RF power source to forming a film over the substrate by reacting the reactant gas with the precursor; and purging the reaction chamber after the film is formed over the substrate. In some embodiments, the plasma source is an inductively coupled plasma source.

### BRIEF DESCRIPTION OF THE DRAWINGS

The present invention can be more fully understood by reading the subsequent detailed description and examples with references made to the accompanying drawings, wherein:

FIG. 1 is a schematic view of a semiconductor processing apparatus according to some embodiments of the present disclosure;

FIG. 2 is a schematic view of a method for forming a film between a gap over a substrate according to some embodiments of the present disclosure;

FIG. 3 is a schematic view of a timing sequence according to some embodiments of the present disclosure;

FIG. 4A is a schematic view of a surface of a substrate according to some embodiments of the present disclosure;

FIG. 4B is diagram of the thickness of the film on the surface of the substrate according to some embodiments of the present disclosure; and

FIGS. 5A through 5C are cross-sectional views of a semiconductor structure according to some embodiments of the present disclosure.

### DETAILED DESCRIPTION OF THE INVENTION

The present disclosure now will be described more fully hereinafter with reference to the accompanying drawings. The present disclosure may, however, be embodied in many different forms and should not be construed as limited to the embodiments set forth herein. Rather, these embodiments are provided so that this disclosure will be thorough and complete, and will fully convey the scope of the present disclosure to one of ordinary skill in the art.

It will be understood that although the terms “first,” “second,” and the like may be used herein to describe various members, regions, layers, and/or portions, these members, regions, layers, and/or portions should not be limited by these terms. The terms do not refer to a specific order, a vertical relationship, or a preference, and are only used to distinguish one member, region, or portion from another member, region, or portion. Accordingly, a first member, region, or portion that will be described below may refer to a second member, region, or portion without departing from the teaching of the present disclosure.

As used herein substantially or about the same means ±5%, ±2%, ±1%, or ±0.5% of another value or shape—e.g., one or more cross-sectional dimensions of the shape. The percentages can be absolute or relative.

In the drawings, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. Further, the drawing figures may be used to illustrate various features, which may not be drawn to scale.

Expressions, such as “at least one of,” when preceding a list of elements, modify the entire list of elements and do not modify the individual elements of the list.

As used herein, “atomic layer deposition”, abbreviated as “ALD”, refers to a method of depositing a film on a substrate by sequentially exposing its surface to alternate gas-phase reactants. In contrast to chemical vapor deposition, the different reactants are not simultaneously present in the reactor, but rather they are introduced as a series of sequential, non-overlapping pulses. In each of these pulses, the reactant reacts with the surface in a self-limiting way or a substantially self-limiting way. Further, ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “boron carbide” or “BₓC_{y}” refers to a material that comprises boron and carbon. In some embodiments, boron carbide may not include significant proportions of elements other than boron and carbon. In some embodiments, the boron carbide comprises B₄C. In some embodiments, the boron carbide may consist essentially of B₄C. In some embodiments, the boron carbide may not include stoichiometric boron carbide. In some cases, the boron carbide can include other elements, such as hydrogen.

As used herein, “boron carbonitride” or “BₓC_{y}N_{z}” refers to a material that that comprises boron, carbon, and nitrogen. Boron carbonitride may be represented by the formula BₓC_{y}N_{z} where the sum of x, y, and z is equal to 3. In some cases, the boron carbonitride may include other elements, such as hydrogen. The boron carbonitride may include boron carbide and boron nitride.

As used herein, “boron nitride” or “BₓN_{y}” refers to a material that that comprises boron and nitrogen. In some embodiments, boron nitride may not include significant proportions of elements other than boron and nitrogen. In some embodiments, the boron nitride comprises BN. In some embodiments, the boron nitride may consist essentially of BN. In some cases, the boron nitride may not include stoichiometric boron nitride. In some cases, the boron nitride can include other elements, such as hydrogen.

As used herein, “boron oxide” or “BₓO_{y}” refers to a material that that comprises boron and oxygen. In some embodiments, boron oxide may not include significant proportions of elements other than boron and oxygen. Boron oxide can be represented by the formula BₓO_{y}, where x can range from about 0 to about 6 and y can range from about 0 to about 3. In some embodiments, the boron oxide comprises B₂O₃. In some embodiments, the boron oxide may consist essentially of B₂O₃. In some cases, the boron oxide may not include stoichiometric boron oxide. In some cases, the boron oxide can include other elements, such as carbon and/or hydrogen.

As used herein, “chemical vapor deposition”, abbreviated as “CVD”, refers to a method of depositing a film on a substrate by exposing its surface to one or more gaseous reactants, which react and/or decompose on the substrate surface to produce a desired film. Typically, CVD is performed by co-introducing the reactants into a reactor.

As used herein, “chemisorption” refers to an adsorption process, caused by a reaction on an exposed surface, which creates, for example, a covalent or ionic bond between the surface and the adsorbate.

As used herein, a “film” refers to a continuous, substantially continuous, or non-continuous material that extends in a direction perpendicular to a thickness direction to cover at least a portion of a surface. A film can include two-dimensional materials, three-dimensional materials, nanoparticles or even partial or full molecular layers or partial or full atomic layers or clusters of atoms and/or molecules. A film may be built up from one or more non-discernable layers (e.g., monolayers or sub-monolayers) to produce a uniform or a substantially uniform material, wherein the number of layers influences the thickness of the material.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein, a “plasma” refers to an ionized gas comprising roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide very different fluxes of the various species.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, “self-limiting” refers to a process that proceeds by a finite course and that terminates once the finite course is complete. For example, a self-limiting surface reaction terminates when the surface becomes saturated and all of the available and/or accessible surface reactive sites are depleted. At maximum one monolayer may be formed on the surface.

As used herein, “silicon carbide” or “SiC” refers to a material that includes silicon and carbon. In some embodiments, silicon carbide may not include significant proportions of elements other than silicon and carbon. Silicon carbide may be represented by the formula SiC. In some embodiments, the silicon carbide comprises SiC. In some embodiments, the silicon carbide may consist essentially of SiC. Silicon carbide need not necessarily be a stoichiometric composition. An amount of silicon can range from 5% to 50%; an amount of carbon can range from about 50% to about 95%. In some embodiments, SiC films may comprise one or more elements in addition to silicon and carbon, such as hydrogen and/or nitrogen.

As used herein, “silicon carbonitride” or “SiₓC_{y}N_{z}” or “SiCN” refers to a material that comprises silicon, carbon, and nitrogen. Silicon carbonitride may be represented by the formula SiₓC_{y}N_{z}. In some embodiments, the silicon carbonitride may comprise more Si—N bonds than Si—C bonds, for example, a ratio of Si—N bonds to Si—C bonds may be from about 1:10 to about 10:1. In some embodiments, the silicon carbonitride films may comprise from about 0% to about 50% carbon on an atomic basis. In some embodiments, the silicon carbonitride may comprise from about 0.1% to about 40%, from about 0.5% to about 30%, from about 1% to about 30%, or from about 5% to about 20% carbon on an atomic basis. In some embodiments, the silicon carbonitride may comprise from about 0% to about 70% nitrogen on an atomic basis. In some embodiments, the silicon carbonitride may comprise from about 10% to about 70%, from about 15% to about 50%, or from about 20% to about 40% nitrogen on an atomic basis. In some embodiments, the silicon carbonitride may comprise about 0% to about 50% silicon on an atomic basis. In some embodiments, the silicon carbonitride may comprise from about 10% to about 50%, from about 15% to about 40%, or from about 20% to about 35% silicon on an atomic basis. In some cases, the silicon carbonitride may include other elements, such as hydrogen. The silicon carbonitride may include silicon carbide and silicon nitride.

As used herein, “silicon nitride” or “SiₓN_{y}” refers to a material that includes silicon and nitrogen. In some embodiments, silicon nitride may not include significant proportions of elements other than silicon and nitrogen. Silicon nitride may be represented by the formula Si₃N₄. In some embodiments, the silicon nitride comprises Si₃N₄. In some embodiments, the silicon nitride may consist essentially of Si₃N₄. In some cases, the silicon nitride may not include stoichiometric silicon nitride. In some cases, the silicon nitride may include other elements, such as carbon, oxygen, and/or hydrogen.

As used herein, “silicon oxide” or “SiOₓ” refers to a material that includes silicon and oxygen. Silicon oxide can be represented by the formula SiOₓ, where x can be between 0 and 2. In some embodiments, silicon oxide may not include significant proportions of elements other than silicon and oxygen. Silicon oxide may be represented by the formula SiO₂. In some embodiments, the silicon oxide comprises SiO₂. In some embodiments, the silicon oxide may consist essentially of SiO₂. In some cases, the silicon oxide may not include stoichiometric silicon oxide. In some cases, the silicon oxide can include other elements, such as carbon, nitrogen, and/or hydrogen.

As used herein, “silicon oxycarbide” or “Si_{z}OₓC_{y}” or “SiOC” refers to material that comprises silicon, oxygen, and carbon. As used herein, unless stated otherwise, SiOC is not intended to limit, restrict, or define the bonding or chemical state, for example, the oxidation state of any of Si, O, C, and/or any other element in the film. In some embodiments, the Si_{z}OₓC_{y} may comprise Si—C bonds and/or Si—O bonds. In some embodiments, the SiOC may comprise Si—C bonds and Si—O bonds and may not comprise Si—N bonds. In some embodiments, the SiOC may comprise Si—H bonds in addition to Si—C and/or Si—O bonds. In some embodiments, the SiOC may comprise more Si—O bonds than Si—C bonds, for example, a ratio of Si—O bonds to Si—C bonds may be from about 1:10 to about 10:1. In some embodiments, the SiOC may comprise from about 0% to about 50% carbon on an atomic basis. In some embodiments, the SiOC may comprise from about 0.1% to about 40%, from about 0.5% to about 30%, from about 1% to about 30%, or from about 5% to about 20% carbon on an atomic basis. In some embodiments, the SiOC may comprise from about 0% to about 70% oxygen on an atomic basis. In some embodiments, the SiOC may comprise from about 10% to about 70%, from about 15% to about 50%, or from about 20% to about 40% oxygen on an atomic basis. In some embodiments, the SiOC may comprise about 0% to about 50% silicon on an atomic basis. In some embodiments, the SiOC films may comprise from about 10% to about 50%, from about 15% to about 40%, or from about 20% to about 35% silicon on an atomic basis. In some embodiments, silicon oxycarbide can be represented by the chemical formula Si_{z}OₓC_{y}, where z can range from about 0 to about 2, x can range from about 0 to about 2, and y can range from about 0 to about 5.

As used herein, “silicon oxycarbonitride” or “Si_{z}OₓC_{y}N_{w}” or “SiOCN” refers to material that comprises silicon, oxygen, nitrogen, and carbon. As used herein, unless stated otherwise, SiOCN is not intended to limit, restrict, or define the bonding or chemical state, for example, the oxidation state of any of Si, O, C, N and/or any other element in the material. In some embodiments, SiOCN is material that can be represented by the chemical formula Si_{z}OₓC_{y}N_{w}, where z can range from about 0 to about 2, x can range from about 0 to about 2, y can range from about 0 to about 2, and w can range from about 0 to about 2.

As used herein, “silicon oxynitride” or “SiOₓN_{y}” refers to a material that includes silicon, oxygen, and nitrogen. As used herein, unless stated otherwise, SiOₓN_{y} is not intended to limit, restrict, or define the bonding or chemical state, for example, the oxidation state of any of Si, O, N and/or any other element in the material. In some embodiments, SiOₓN_{y} is material that can be represented by the chemical formula SiOₓN_{y}, where x can range from about 0 to about 2, y can range from about 0 to about 2. The silicon oxynitride may include silicon oxide and silicon nitride.

As used herein, a “substrate” refers to an underlying material or materials that may be used to form, or upon which, a device, a circuit, material, or material layer may be formed. The substrate may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. The substrate can include various topologies, such as gaps, including recesses, lines, trenches, or spaces between elevated portions, such as fins, and the like formed within or on at least a portion of a layer of the substrate.

As used herein, an “ion trap” refers to a structure, region, device, or configuration within a semiconductor processing chamber, such as a plasma-enhanced atomic layer deposition (PE-ALD) or radical-enhanced atomic layer deposition (RE-ALD) chamber, that is designed to selectively capture, retain, and control ionic species generated during deposition processes. The ion trap may be integrated into or positioned adjacent to the interior surfaces of the chamber, including, for example, chamber walls, gas distribution plates, or other internal components, to manage the energy, directionality, and concentration of ions within the reaction space. By influencing ion trajectories and reducing undesirable ion bombardment or plasma-induced damage to substrates and underlying device structures, the ion trap can help maintain optimal conditions for uniform and conformal film growth. The ion trap may be formed from various conductive, semiconductive, or dielectric materials, and can include engineered geometries, patterned surfaces, coatings, or other configurations tailored to the specific process chemistries, power levels, and plasma conditions of interest. In certain embodiments, the ion trap may be dynamically adjusted or tuned to accommodate changing process parameters, thereby improving process stability, film quality, and overall device performance in advanced semiconductor fabrication environments.

As used herein, a “substituent” refers to an atom or a group of atoms that replaces one or more atoms (such as a hydrogen atom) or groups of atoms in a parent compound, thereby resulting in a new compound. The substituent is substituted for the original atom or a group of atoms in the parent molecule. For simplicity, a substituent may be indicated in a chemical formula as an “R” group and each “R” group in a compound may be independently selected unless otherwise specifically indicated that this is not the case. Examples of substituent groups include, but are not limited to: a hydrogen atom (H); an “alkyl group”, such as a saturated linear or branched C₁ to C₁₀ hydrocarbons, preferably C₁ to C₆ hydrocarbons (e.g., methyl, ethyl, propyl, isopropyl, butyl, i-butyl, s-butyl, t-butyl, pentyl, 3-pentyl, neo-pentyl, and hexyl); a “cycloalkyl group”, such as C₃ to C₆ cyclic hydrocarbons (e.g., cyclopropyl, cyclobutyl, cyclopentyl, and cyclohexyl); an “alkenyl group”, such as C₂ to C₆ linear or branched unsaturated hydrocarbons (e.g., vinyl, allyl, propenyl, butenyl, pentenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl, and methyl, dimethyl, or ethyl cyclopentadienyl groups; a hydroxy group (OH); an “alkoxy group”, such as a linear or branched C₁ to C₁₀ alkoxy group, typically a C₁ to C₄ alkoxy group (e.g., methoxy, ethoxy, n-propoxy, i-propoxy, butoxy, iso-butoxy, sec-butoxy, and tert-butoxy); a hydroxyalkyl group such as a linear or branched a C₁ to C₁₀ hydroxyalkyl, typically a linear or branched C₁ to C₄ hydroxyalkyl (e.g., hydroxymethyl, hydroxyethyl, hydroxypropyl, hydroxybutyl, hydroxypentyl, and hydroxyhexyl); an “alkoxycarbonyl group”, such as a linear or branched C₁ to C₆ carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group”, such as a linear or branched C₁ to C₆ thiols (e.g., thiolmethyl, thiolethyl, thiolpropyl, thiolbutyl, thiolpentyl, and thiolhexyl); a halide (X), such as fluoride (F), chloride (Cl), bromide (Br), and iodide (I); and an “haloalkyl group”, such as a linear or branched C₁ to C₆ alkylhalides having one or more halogen atoms (e.g., iodomethyl, bromomethyl, chloromethyl, fluoromethyl, trifluoromethyl, 2-chloroethyl, 2-fluoroethyl, 2,2,2-trifluoroethyl, and pentafluoroethyl). A substituent group may, in and of itself, be substituted. For example, a hydroxyalkyl group is a substituted alkyl group, where a H atom on the alkyl group is replaced with an OH group.

As used herein, “radicalizing” refers to a process that involves converting stable precursor or reactant gases into radicals—highly reactive neutral species with unpaired electrons—in a semiconductor deposition chamber environment, such as during plasma-enhanced atomic layer deposition (PE-ALD) or radical-enhanced atomic layer deposition (RE-ALD). These radicals may be generated by introducing energy sources (e.g., plasma, photons, thermal energy) that dissociate gas-phase molecules into more reactive fragments. The radicalizing process can occur within, or in proximity to, the deposition chamber and may be achieved through dedicated radical-generating zones, plasma sources, radical injectors, or other field-generating components. By producing a controlled population of radicals, the radicalizing process enhances reaction kinetics, improves the overall chemical reactivity at the substrate surface, and enables more uniform, conformal, and efficient film deposition. These radicals may react with various substrate surfaces, including silicon-based materials, metals, nitrides, oxides, and other semiconductor or dielectric materials, facilitating tailored surface modification or layer formation. The radicalizing process may be dynamically adjusted by controlling parameters such as gas flow, chamber pressure, plasma power, or residence time of the precursor species, thereby allowing for fine-tuning of the film properties, improved process stability, and enhanced device performance in advanced semiconductor fabrication environments.

Articles “a” or “an” refer to a species or a genus including multiple species, depending on the context. As such, the terms “a/an”, “one or more” and “at least one” can be used inter-changeably herein. It is also to be noted that the terms “comprising”, “including”, and “having” can be used interchangeably.

The term “about” generally refers to a range of numbers that is considered equivalent to the recited value (e.g., having the same function or result). In some instances, the term about may include numbers that are rounded to the nearest significant figure.

The term “essentially” as applied to a composition, a method, or a system generally means that the additional components do not substantially modify the properties and/or function of the composition, the method, or the system.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%. “At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

The present disclosure generally relates to methods of forming a material between a gap over a substrate using plasma enhanced atomic-layer deposition (PE-ALD) and apparatus for performing such methods, and in particular to the use of a pulsed bottom RF power to reduce damage to the underlying layer. More specifically, the present disclosure generally relates to methods of forming a film between the gap over the substrate using radical-enhanced atomic-layer deposition (RE-ALD) and systems for performing such methods, and in particular to the use of a pulsed bottom RF power to improve the film uniformity. Various aspects of the methods and systems and the benefits derived therefrom will now be described.

Finding improved chemical precursors for ALD processes is an ongoing effort, as increasingly stringent material and process requirements need to be met in order to enable improvement of semiconductor devices. In general, it is difficult to control plasma density and ion energy separately because plasma density and ion energy are controlled by the same RF power. While using low ion energy at the substrate level to improve underlayer damage, there is a problem where the density of the film is decreased, resulting in an increase in etch rate and a decrease in the density uniformity of the film. In this regard, disclosed herein are methods and systems for depositing a film to improve underlayer damage at a high film quality. The methods and systems disclosed herein advantageously use the pulsed bottom RF power for forming the material between the gap over the substrate. The disclosed methods can improve the uniformity and conformality of the film, while minimizing the damage to the underlying liner. These and other advantages will be apparent from the disclosure of the various aspects, embodiments, and configurations contained herein.

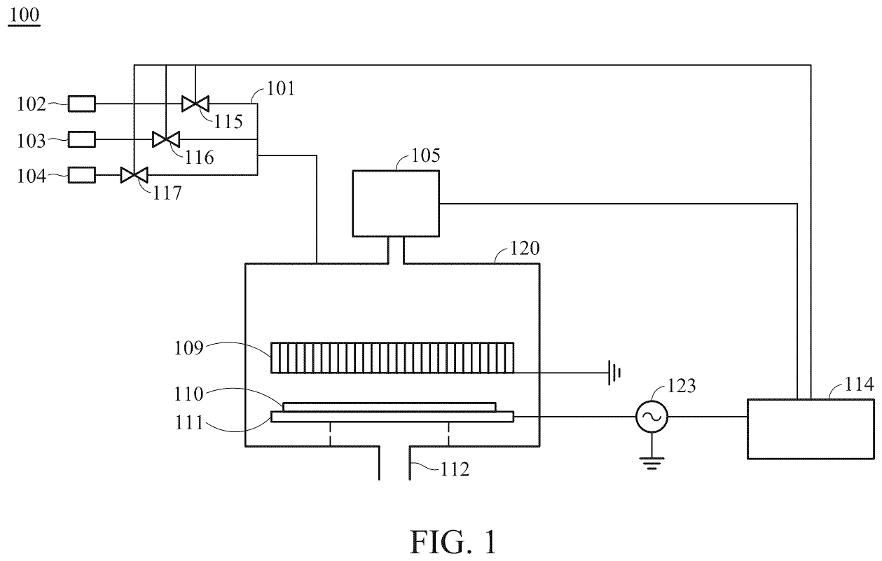

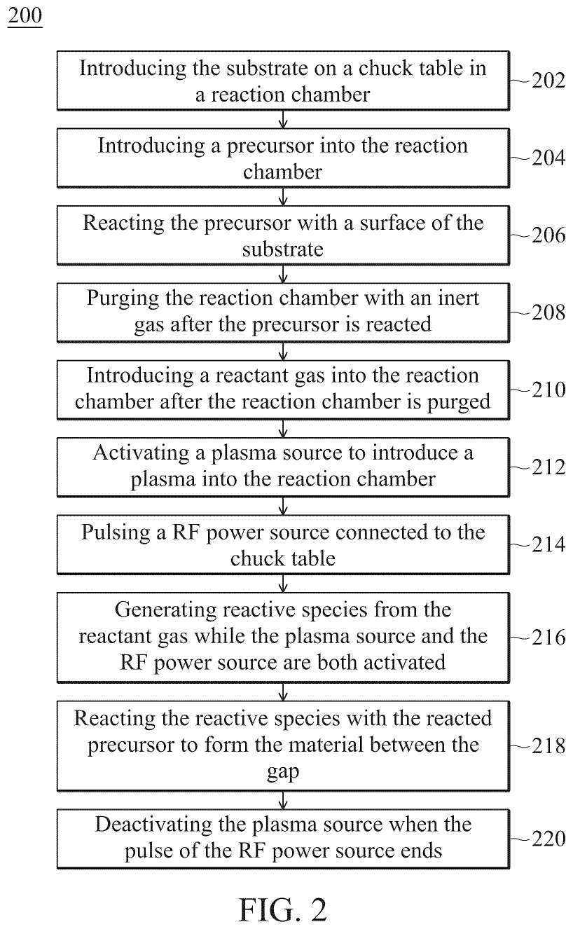

Please refer to FIG. 1, FIG. 1 is a schematic view of a semiconductor processing apparatus 100 according to some embodiments of the present disclosure. The semiconductor processing apparatus 100 is an implementation of method 200, which will further discussed in accompany with FIG. 2. Therefore, the element and/or component describe herein can be connected to method 200.

A carrier gas is supplied from a carrier gas source 102 through a gas manifold 101 into the reaction chamber 120. The carrier gas flows into the reaction chamber 120 where a substrate (for example, a wafer) 110 is placed. A precursor is also supplied from a precursor source 103, in the form of a gas, through the gas manifold 101 into the reaction chamber 120. The precursor many be vaporized and entrained in or pulsed into the carrier gas. A reactant is supplied from a reactant source 104, in the form of a gas, through the gas manifold 101 into the reaction chamber 120. That is, the precursor source 103 and the reactant source 104 are in fluid communication with the reaction chamber 120. In some embodiments, the reaction chamber 120 can form part of an ALD assembly and may be a single wafer reactor or it may comprise one or more multi-station deposition chambers. Alternatively, the reactor may be a batch reactor. The various steps of the method can be performed within a single reaction chamber, or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including a reaction chamber can be provided with a heater to activate the reactions by elevating the temperature of one or more of the substrate, the reactants, the precursors, and other gasses. The reactants, precursors, and other gasses may be introduced into the chamber using a showerhead-type reaction chamber or cross-flow reaction chamber, or a combination thereof.

The semiconductor processing apparatus 100 is also configured to allow for the introduction of other gases, such as other reactant (reactive gas) and other gases (e.g., other carrier gases, precursors or reactive gases, carrier, dilutant, process, feed, and/or purging gases), into the reaction chamber 120. Thus, the semiconductor processing apparatus 100 may include other sources (not shown). Unreacted gases and gaseous reaction by-products exit the reaction chamber 120 through an exhaust line 112. The reaction chamber 120 may optionally be equipped with a purge line (not shown) and/or a pump line (not shown) coupled to a vacuum pump (not shown) so that the reaction chamber 120 may be purged between the various reaction cycles.

A plasma source 105 is located at the upper portion of the reaction chamber 120 and configured to generate plasma. The plasma source 105 is activated to introduce the plasma into the reaction chamber 120. In some embodiments, the plasma source 105 is an inductively coupled plasma source. However, the present disclosure is not limited thereto. The semiconductor processing apparatus 100 may include a substrate support 111 that is located at a lower portion of the reaction chamber 120 and configured to support a substrate 110. The ion filter 109 is positioned between the plasma source 105 and the substrate support 111. In some embodiments, the ion filter 109 separates the reaction chamber 120 into the upper portion and the lower portion. The ion filter 109 restricts the plasma from the plasma source 105 to the upper portion of the reaction chamber 120 above the ion filter 109. For example, an electrically grounded mesh plate may be used as the ion filter 109. In some embodiments, the mesh plate is a metal plate (such as aluminum) including hundreds of holes in a showerhead-like pattern that lets radical species pass through to the substrate 110 while trapping the ions. For instance, the mesh plate may comprise between about 1,000 to about 5,000 holes, each hole having a diameter between about 0.5 mm to about 2 mm. The addition of the ion filter 109, beneficially reduces or even eliminates interactions of electrons and ions with the surface of the substrate 110 by restricting the first plasma to the upper portion of the reaction chamber 120.

A RF power source 123 is connected to the substrate support 111 and configured to distribute plasma redial on the substrate 110. That is, the RF power source 123 allows for the substrate support 111 to be biased relative to the ion filter 109. The semiconductor processing apparatus 100 also includes a controller 114 operably connected to a first valve 115, a second valve 116, and a third valve 117, the plasma source 105, the RF power source 123, and other components (not shown). The controller 114 is configured and programmed to independently control (e.g., turn on and off, etc.) the supply of the various gases (e.g., carrier gas, precursor, reactant, and any dilutant, process, feed, and/or purging gases etc.), the plasma source 105, and the RF power source 123, as required, to deposit a film on the surface of the substrate 110. In some embodiments, the controller 114 is configured to control the first valve 115 to flow the carrier gas from the carrier gas source 102 into the reaction chamber 120. The controller 114 is further configured to open the second valve 116 to flow the precursor from the precursor source 103 into the reaction chamber 120. After a set period of time, the controller 114 closes the second valve 116 to the precursor source 103 and opens the third valve 117 to flow the reactant from the reactant source 104 into the reaction chamber 120 and to activate the plasma source 105 and the RF power source 123. After a set period of time, the controller 114 closes the third valve 117 to the reactant source 104 and turns off the plasma source 105 and the RF power source 123. The controller 114 is programed to repeat the various process steps to grow a film on the surface of the substrate 110. The controller 114 may be programed to perform other process steps in between these various steps.

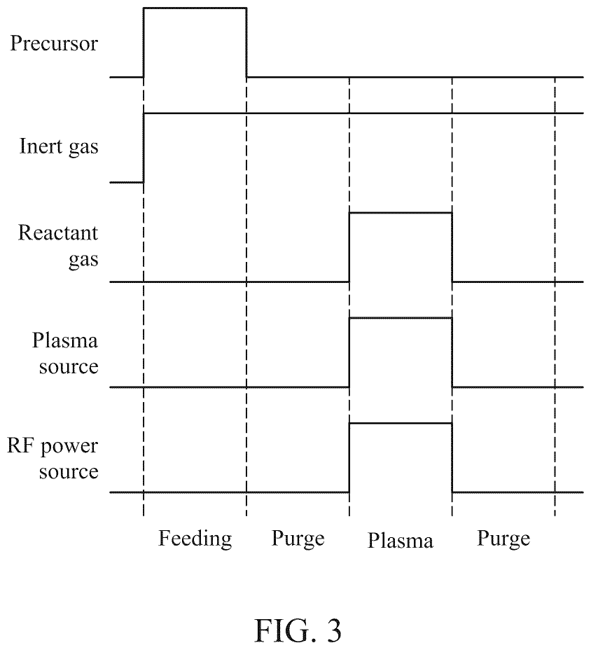

The semiconductor processing apparatus or system disclosed herein can include additional sources and additional components, which are not shown in FIG. 1, such as those typically found on semiconductor processing apparatus. For example, the semiconductor processing apparatus 100 may be provided with one or more heaters and one or more temperature regulators to activate the reactions by elevating the temperature of one or more of the substrates and/or gases entering into the reaction chamber (e.g., carrier gas, precursor, reactive gas, etc.). The semiconductor processing apparatus 100 may also be provided with a pumping system for purging the reaction chamber in between the various processing steps. The detail of the operation of the semi-conductor processing apparatus 100 will be further discussed below in accompany with FIGS. 2 and 3.

Please refer to FIG. 2, FIG. 2 is a schematic view of a method 200 for forming a material between a gap over the substrate (for example, the substrate 110) according to some embodiments of the present disclosure. In step 202, the method 200 includes introducing the substrate on a substrate support in a reaction chamber. In some embodiments, the substrate 110 is introduced on the substrate support 111 in the reaction chamber 120. In step 204, the method 200 includes introducing a precursor into the reaction chamber. In some embodiments, the precursor introduced into the reaction chamber 120. For example, the precursor includes silane, disilane, trisilane, di(isopropylamino)silane, dichlorosilane, trichlorosilane, or monomethylsilane. However, the present disclosure is not limited thereto.

Next, in step 206, the method 200 includes reacting the precursor with a surface of the substrate. In some embodiments, the precursor reacts with a surface (for example, the upper surface) of the substrate 110. In some embodiments, the flow rate of the introduced precursor is higher than 0 and lower than 3000 sccm, such as about 500 sccm, about 1000 sccm, about 1500 sccm, about 2000 sccm, about 2500 sccm, etc. In step 208, the method 200 includes purging the reaction chamber with an inert gas after the precursor is reacted. In some embodiments, the reaction chamber 120 is purged with the inert gas after the reaction between the precursor and the surface of the substrate 110 ends. It should be noted that in some embodiments, the purge step (for example, the step 208) is optional and can be omitted. In step 210, the method 200 includes introducing a reactant gas into the reaction chamber after the reaction chamber is purged (or after the precursor reacts with the surface of the substrate 110 if the step 208 is omitted). In some embodiments, the reactant gas is introduced into the reaction chamber 120 after the reaction chamber 120 is purged (i.e., the remaining precursor is exhausted from the reaction chamber 120). For example, the reactant gas includes oxygen or hydrogen peroxide. In some embodiments, the flow rate of the introduced reactant gas is higher than 0 and lower than 3000 sccm, such as about 500 sccm, about 1000 sccm, about 1500 sccm, about 2000 sccm, about 2500 sccm, etc. However, the present disclosure is not limited thereto.

Then, in step 212, the method 200 includes activating a plasma source to introduce a plasma into the reaction chamber. In some embodiments, the plasma source 105 is activated to introduce the plasma into the reaction chamber 120. In some embodiments, the power of the plasma source 105 is higher than 0 and lower than 6000 W, such as about 500 W, about 1000 W, about 1500 W, about 2000 W, about 2500 W, about 3000 W, about 3500 W, about 4000 W, about 4500 W, about 5000 W, about 5500 W, etc. However, the present disclosure is not limited thereto. In step 214, the method 200 includes pulsing a RF power source connected to the substrate support. In some embodiments, the RF power source 123, which is connected to the substrate support 111, is pulsed (i.e., activated). In some embodiments, the period of time of introducing the plasma into the reaction chamber 120 is substantially the same as the period of time of pulsing the RF power source 123 connected to the substrate support 111. In some embodiments, the power of the RF power source 123 is higher than 0 and lower than 1000 W, such as about 100 W, about 200 W, about 300 W, about 400 W, about 500 W, about 600 W, about 700 W, about 800 W, about 900 W, etc. In some embodiments, the duty cycle of the RF power source is higher than 10% and lower than 90%, such as about 20%, about 30%, about 40%, about 50%, about 60%, about 70%, about 80%, etc. In some embodiments, the pulse frequency of the RF power is higher than 0 and lower than 100 kHz, such as about 10 kHz, about 20 kHz, about 30 kHz, about 40 kHz, about 50 kHz, about 60 kHz, about 70 kHz, about 80 kHz, about 90 kHz, etc. In some embodiments, the RF frequency of the RF power is higher than 13.56 MHz and lower than 60 MHz, such as about 15 MHz, about 20 MHz, about 30 MHz, about 40 MHz, about 50 MHz, etc. However, the present disclosure is not limited thereto.

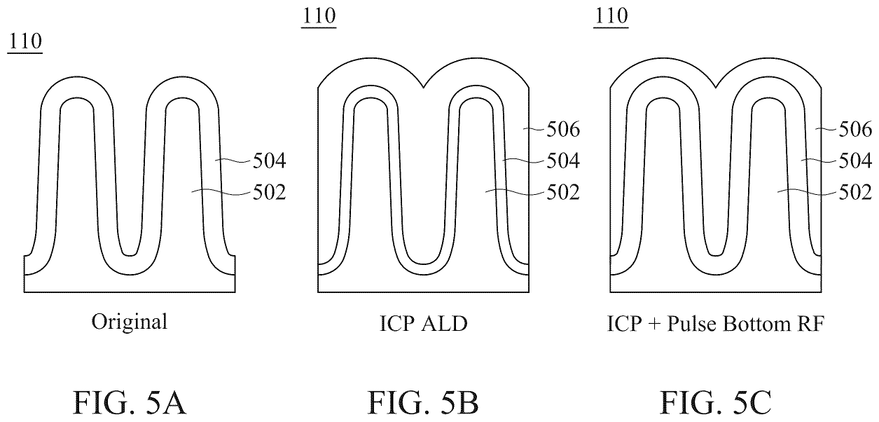

In step 216, the method 200 includes generating reactive species from the reactant gas while the plasma source and the RF power source are both activated. In some embodiments, the reactive species are generated from the reactant gas while the plasma source 105 and the RF power source 123 are both activated. In step 218, the method 200 includes reacting the reactive species with the reacted precursor to form the material between the gap (which will be illustrated in FIGS. 5A through 5C). In some embodiments, the process pressure of reacting the reactant gas with the precursor is higher than 1 torr and lower than 9 torr, such as about 2 torr, about 3 torr, about 4 torr, about 5 torr, about 6 torr, about 7 torr, about 8 torr, etc. In some embodiments, the process temperature of reacting the reactant gas with the precursor is higher than 0 °C and lower than 1000 °C, such as about 100 °C, about 200 °C, about 300 °C, about 400 °C, about 500 °C, about 600 °C, about 700 °C, about 800 °C, about 900 °C, etc. However, the present disclosure is not limited thereto. In step 220, the method 200 includes deactivating the plasma source when the pulse of the RF power source ends. In some embodiments, the plasma source 105 is deactivated when the pulse of the RF power source 123 ends. In some embodiments, the reaction chamber 120 is purged with the inert gas after the plasma source 105 is deactivated. It should be noted that in some embodiments, the above purge step is optional and can be omitted.

It should be noted that multiple steps are provided in a particular order as set forth above. However, the present disclosure is not limited thereto. Those skilled in the art would be able to add, substitute, repeat particular steps in the method 200 in order to form the material between the gap over the substrate 110, and some of the above steps may be performed simultaneously. These variations are also included within the scope of the present disclosure, and will not be listed one-by-one as follows.

FIG. 3 is a schematic view of a timing sequence according to some embodiments of the present disclosure. As shown in FIG. 3, in the feeding step, the precursor and the inert gas are introduced into the reaction chamber 120. In particular, the precursor source 103 is activated and the second valve 116 is opened to flow the precursor from the precursor source 103 into the reaction chamber 120. For example, the precursor includes silane, disilane, trisilane, di(isopropylamino)silane, dichlorosilane, trichlorosilane, or monomethylsilane. However, the present disclosure is not limited thereto. Next, in the purge step, the second valve 116 is closed to shut down the precursor from flowing into the reaction chamber 120. The inert gas is still supplied into the reaction chamber 120 to purge the reaction chamber 120. It should be noted that in some embodiments, the purge step is optional and can be omitted.

Next, in the plasma step, the reactant gas is introduced into the reaction chamber 120 after the reaction chamber 120 is purged. In some embodiments, the reactant gas is introduced into the reaction chamber 120 by activating the reactant source 104 and opening the third valve 117. For example, the reactant gas includes oxygen or hydrogen peroxide. In some embodiments, the flow rate of the introduced reactant gas is higher than 0 and lower than 3000 sccm, such as about 500 sccm, about 1000 sccm, about 1500 sccm, about 2000 sccm, about 2500 sccm, etc. However, the present disclosure is not limited thereto. Meanwhile, in the plasma step, the plasma source 105 is activated to introduce the plasma into the reaction chamber 120. In some embodiments, the power of the plasma source 105 is higher than 0 and lower than 6000 W, such as about 500 W, about 1000 W, about 1500 W, about 2000 W, about 2500 W, about 3000 W, about 3500 W, about 4000 W, about 4500 W, about 5000 W, about 5500 W, etc.

In the plasma step, the RF power source 123, which is connected to the substrate support 111, is pulsed (i.e., activated). In some embodiments, the period of time of introducing the plasma into the reaction chamber 120 is substantially the same as the period of time of pulsing the RF power source 123. In some embodiments, the power of the RF power source 123 is higher than 0 and lower than 1000 W, such as about 100 W, about 200 W, about 300 W, about 400 W, about 500 W, about 600 W, about 700 W, about 800 W, about 900 W, etc. In some embodiments, the duty cycle of the RF power source is higher than 10% and lower than 90%, such as about 20%, about 30%, about 40%, about 50%, about 60%, about 70%, about 80%, etc. In some embodiments, the pulse frequency of the RF power is higher than 0 and lower than 100 kHz, such as about 10 kHz, about 20 kHz, about 30 kHz, about 40 kHz, about 50 kHz, about 60 kHz, about 70 kHz, about 80 kHz, about 90 kHz, etc. In some embodiments, the RF frequency of the RF power is higher than 13.56 MHz and lower than 60 MHz, such as about 15 MHz, about 20 MHz, about 30 MHz, about 40 MHz, about 50 MHz, etc. However, the present disclosure is not limited thereto.

During the plasma step, the reactive species are generated from the reactant gas while the plasma source 105 and the RF power source 123 are both activated. The reactive species react with the reacted precursor to form the material between the gap (which will be illustrated in FIGS. 5A through 5C). In some embodiments, the process pressure of reacting the reactant gas with the precursor is higher than 1 torr and lower than 9 torr, such as about 2 torr, about 3 torr, about 4 torr, about 5 torr, about 6 torr, about 7 torr, about 8 torr, etc. In some embodiments, the process temperature of reacting the reactant gas with the precursor is higher than 0 °C and lower than 1000 °C, such as about 100 °C, about 200 °C, about 300 °C, about 400 °C, about 500 °C, about 600 °C, about 700 °C, about 800 °C, about 900 °C, etc. However, the present disclosure is not limited thereto.

Next, in the purge step, the plasma source 105 and the RF power source 123 are both deactivated and the third valve 117 is closed to shut down the reactant gas from flowing into the reaction chamber 120. The inert gas is still supplied into the reaction chamber 120 to purge the reaction chamber 120. It should be noted that the timing sequence shown in FIG. 3 can be repeated to form the material between the gap over the substrate 110. It should be noted that in some embodiments, the purge step is optional and can be omitted.

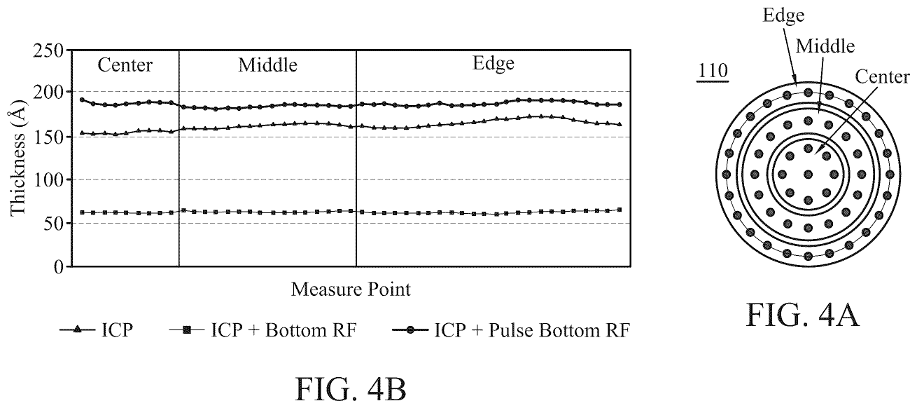

FIG. 4A is a schematic view of a surface of the substrate 110 according to some embodiments of the present disclosure. FIG. 4B is diagram of the thickness of the film on the surface of the substrate 110 according to some embodiments of the present disclosure. As shown in FIG. 4A, a plurality of measuring points are arranged on the substrate 110. The substrate 110 are divided into a center region, a middle region, and an edge region, and the middle region is sandwiched between the center region and the edge region. These measuring points are distributed in the center region, the middle region, and the edge region of the substrate 110. In some embodiments, the distance between the center of the substrate 110 and the center region can be ranged from 0 to about 49 mm. The distance between the center of the substrate 110 and the middle region can be ranged from about 49 nm to about 98 mm. The distance between the center of the substrate 110 and the edge region can be ranged from about 98 nm to about 147 mm. However, the present disclosure is not limited thereto.

As shown in FIG. 4B, when using the plasma source 105 only, the thickness of the deposited film is not uniform. For example, the thickness of the film deposited using the plasma source 105 only is thicker in the edge portion of the substrate 110. In addition, when using the plasma source 105 and continuously-activated RF power source 123, the thickness of the deposited film is relatively uniform. However, the thickness of the deposited film is also relatively low and therefore more process time and cost are required. When using the plasma source 105 and pulsed RF power source 123, the thickness of the deposited film is highly uniform and higher than other processes. Accordingly, the deposition of the film with the pulsed bottom RF power may improve the film uniformity.

FIGS. 5A through 5C are cross-sectional view of a semiconductor structure according to some embodiments of the present disclosure. As shown in FIG. 5A, the substrate 110 includes a plurality of fins 502, and a liner 504 formed on the fins 502. For example, the liner 504 comprises SiN or other dielectric materials. As shown in FIGS. 5B and 5C, a material 506 is formed over the liner 504 and between the gap of the fins 502. For example, the liner 504 comprises SiO or other dielectric materials. It should be noted that FIG. 5B illustrates the deposition of the material 506 using the plasma source 105 only, and FIG. 5C illustrates the deposition of the material 506 using the plasma source 105 and pulsed RF power source 123. Accordingly, the deposition using the plasma source 105 and pulsed RF power source 123 may cause less damage to the underlying liner 504 than using the plasma source 105 only. That is, the liner 504 is relatively thick after the deposition of the material 506, which also improve the film uniformity and quality.

The methods and systems disclosed herein may be used to deposit a number of films, such as, by way of non-limiting example, silicon (Si) containing films and boron (B) containing films as well as metal containing films, metal oxide containing films, and metal nitride containing films such as films comprising aluminum (Al), molybdenum (Mo), titanium (Ti), hafnium (Hf), tungsten (W), magnesium (Mg), tantalum (Ta), strontium (Sr), and the like. The methods and systems disclosed herein may be used to increase the reactivity of certain precursors such as, by way of non-limiting example, silicon-containing precursors, boron-containing precursors, and metal containing precursors, such as those precursors comprising aluminum, molybdenum, titanium, hafnium, tungsten, magnesium, tantalum, strontium, and the like. The precursor, and the radicalized precursor formed therefrom, may comprise one or more of silicon, boron, and a metal selected from the group consisting of aluminum, molybdenum, titanium, hafnium, tungsten, magnesium, tantalum, and strontium. Suitable precursors may include those which are known to be useful in CVD process. In some embodiments, the precursor may be useful in CVD-type deposition processes, but it may be unreactive in ALD-type deposition processes. In such a case, radicalization of the precursor makes it reactive in ALD-type deposition processes.

In some embodiments, the reactive gas may be an oxygen containing gas. For example, the oxygen containing gas may be selected from one or more of oxygen (O₂), ozone (O₃), water (H₂O), hydrogen peroxide (H₂O₂), an alcohol (ROH, where R is an alkyl or aryl group) such as methanol (CH₃OH) and ethanol (C₂H₅OH), nitrogen dioxide (NO₂), nitrous oxide (N₂O), and oxygen atoms (O*) created in a plasma. In some embodiments, the reactive gas may be a nitrogen containing gas. For example, the nitrogen containing gas may be selected from one or more of ammonia (NH₃), hydrazine (N₂H₄), nitric oxide (NO), and activated nitrogen (N₂), activated ammonia (NH₃), and nitrogen atoms (N*) created in a plasma. In some embodiments, the reactive gas may be selected from one or more of hydrogen (H₂) and hydrogen atoms (H*) created in a plasma. In some embodiments, the reactive gas comprises one or more of O₂, H₂O, NH₃, and H₂. In some embodiments, the reactive gas may comprise O*, N*, H*, and combinations thereof.

The methods and systems disclosed herein can provide several benefits, including improving the underlayer damage and forming material with high quality and high deposition rate. The methods and systems disclosed herein advantageously use the pulsed bottom RF power for forming the material between the gap over the substrate. The disclosed methods can improve the uniformity and conformality of the film, while minimizing the damage to the underlying liner. These and other advantages will be apparent from the disclosure of the various aspects, embodiments, and configurations contained herein.

Although embodiments of the present disclosure and their advantages have been described in detail, it should be understood that various changes, substitutions and alterations may be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, the scope of the present disclosure is defined by the scope of the appended claims. In addition, each scope of the claims is constructed as a separate embodiment, and various combinations of the claims and combinations of embodiments are within the scope of the present disclosure.

What is claimed is:

1. A method for forming a film between a gap over a substrate, comprising:
introducing the substrate on a substrate support in a reaction chamber;
introducing a precursor into the reaction chamber;
reacting the precursor with a surface of the substrate;
introducing a plasma into the reaction chamber from a plasma source;
introducing a reactant gas into the reaction chamber;
pulsing a RF power source connected to the substrate support;
generating reactive species from the reactant gas while the plasma source and the RF power source are both activated; and
reacting the reactive species with the precursor on the surface to form the film over the substrate.

2. The method as claimed in claim 1, wherein the precursor comprises silane, disilane, trisilane, di(isopropylamino)silane, dichlorosilane, trichlorosilane, or monomethylsilane.

3. The method as claimed in claim 1, wherein the reactant gas comprises oxygen or hydrogen peroxide.

4. The method as claimed in claim 1, wherein a period of time of introducing the plasma into the reaction chamber is substantially the same as a period of time of pulsing the RF power source connected to the substrate support.

5. The method as claimed in claim 1, further comprising a purge step after introducing the precursor into the reaction chamber, and before introducing the reactant gas into the reaction chamber.

6. The method as claimed in claim 1, wherein a flow rate of the introduced precursor is higher than 0 and lower than 3000 sccm.

7. The method as claimed in claim 1, wherein a flow rate of the introduced reactant gas is higher than 0 and lower than 3000 sccm.

8. The method as claimed in claim 1, wherein a power of the plasma source is higher than 0 and lower than 6000 W.

9. The method as claimed in claim 1, wherein a power of the RF power source is higher than 0 and lower than 1000 W.

10. The method as claimed in claim 1, wherein a duty cycle of the RF power source is higher than 10% and lower than 90%.

11. The method as claimed in claim 1, wherein a pulse frequency of the RF power is higher than 0 and lower than 100 kHz.

12. The method as claimed in claim 1, wherein a RF frequency of the RF power is higher than 13.56 MHz and lower than 60 MHz.

13. The method as claimed in claim 1, wherein a process pressure of reacting the reactant gas with the precursor is higher than 1 torr and lower than 9 torr.

14. The method as claimed in claim 1, wherein a process temperature of reacting the reactant gas with the precursor is higher than 0 °C and lower than 1000 °C.

15. A method for forming a material between a gap over a substrate, comprising:
introducing the substrate on a substrate support in a reaction chamber;
introducing a precursor into the reaction chamber;
reacting the precursor with a surface of the substrate;
purging the reaction chamber with an inert gas after the precursor is reacted;
introducing a reactant gas into the reaction chamber after the reaction chamber is purged;
activating a plasma source to introduce a plasma into the reaction chamber;
pulsing a RF power source connected to the substrate support;
generating reactive species from the reactant gas while the plasma source and the RF power source are both activated;
reacting the reactive species with the reacted precursor to form the material between the gap; and
deactivating the plasma source when the pulse of the RF power source ends.

16. The method as claimed in claim 15, further comprising:
introducing the inert gas into the reaction chamber while the precursor and the reactant gas are introduced into the reaction chamber.

17. The method as claimed in claim 16, further comprising:
purging the reaction chamber with the inert gas after the plasma source is deactivated.

18. A semiconductor processing apparatus, comprising:
a reaction chamber;
a plasma source, located at an upper portion of the reaction chamber;
a substrate support, located at a lower portion of the reaction chamber and supporting a substrate;
an ion filter, located between the plasma source and the substrate support;
a RF power source, connected to the substrate support and configured to distribute plasma redial on the substrate; and
a precursor source and a reactant source in fluid communication with the reaction chamber.

19. The semiconductor processing apparatus as claimed in claim 18, further comprising a controller, configured to:
introducing a precursor from the precursor source into the reaction chamber;
purging the reaction chamber after the precursor is introduced;
introducing a reactant gas from the reactant source into the reaction chamber;
activating the plasma source and pulsing the RF power source to forming a film over the substrate by reacting the reactant gas with the precursor; and
purging the reaction chamber after the film is formed over the substrate.

20. The semiconductor processing apparatus as claimed in claim 18, wherein the plasma source is an inductively coupled plasma source.
